(19) United States
(12) Patent Application Publication
(10) Pub. No.: US 2001/0006847 A1
(43) Pub. Date: Jul. 5, 2001

(54) Method for contact size control for nand technology

(75) Inventors: John JianShi Wang, San Jose, CA (US); Kent Kuohua Chang, Cupertino, CA (US); Hao Fang, Cupertino, CA (US); Kelwin King Wai Ko, San jose, CA (US); Mark S. Chang, Los Altos, CA (US); Angela T. Hui, Fremont, CA (US)

Correspondence Address: Sawyer Law Group LLP, P.O. Box 51418, Palo Alto, CA, 94303, US

(73) Assignee: Advanced Micro Devices, Inc.

(21) Appl. No.: 09/775,723

(22) Filed: Feb. 1, 2001

Related U.S. Application Data
(62) Division of application No. 09/376,396, filed on Aug. 18, 1999.

(51) Int. Cl. H01L 23/48; H01L 23/52; H01L 29/40

(52) U.S. Cl. 438/640; 257/774; 438/637; 438/621

(57) ABSTRACT

The present invention provides a method for providing an interconnect in a flash memory device. A first embodiment includes forming at least one contact hole in a peripheral area of the device; bombarding a bottom of the at least one contact hole with ions, where the ions break down undesired oxide residing at the bottom of the at least one contact hole; depositing a barrier metal layer into the at least one contact hole, where the barrier metal layer breaks down remaining undesired oxide at the bottom of the at least one contact hole, and where bombarding with the ions and the depositing of the barrier metal layer minimize an undesired widening of the at least one contact hole; and depositing a contact material into the at least one contact hole. With the first embodiment, both the ions and the titanium break down the undesired oxide while neither breaks down the desired oxide at the sides of the contact hole to a significant degree. Thus, the undesired oxide at the bottom of the contact hole is removed while the enlargement of the contact hole is minimized. A second embodiment of the method, a contact hole having tapered sides with a top being wider than a bottom is used, where the tapered sides minimizes chances of inadvertently etching any field oxide adjacent to the contact hole. In a third embodiment of the method, the first and second embodiments are combined, minimizing the enlargement of the contact hole and the chances of inadvertently etching the field oxide simultaneously. The reliability of the device is thus increased.

### FIELD OF THE INVENTION

The present invention relates to semiconductor devices, and more particularly to contacts in semiconductor devices.

### BACKGROUND OF THE INVENTION

Semiconductor memory devices include NAND-type flash memory devices. Such memory devices typically comprise a high density core area and a low density peripheral area with cells on a single substrate. Several layers of cells may be formed on the same wafer. FIG. 1 illustrates a cell 100 in the peripheral area in a conventional flash memory device. Many such cells typically reside in the peripheral area. The cell 100 includes a substrate 102, field oxide 104, a stack structure 106, spacers 108, and source/drain regions 110. Although a cell with a n−/n+ source/drain regions is shown, they may also be a p−/p+ source/drain regions. The field oxide 104 separates the cell 100 from other adjacent cells (not shown). The cell 100 is covered by a layer of oxide 112 to insulate this layer of cells from subsequent layers of cells on the wafer (not shown). The cell 100 is connected to other cells in the device through a metal interconnect 114 according to the circuit configuration. The metal interconnect 114 typically comprises a contact plug 116 and a metal line 118.

In a conventional cell, the metal interconnect 114 is formed by first masking the oxide 112 for the purpose of etching a contact hole in the oxide 112. The contact hole will eventually contain the contact plug 116. Since the etching process leaves a small amount of undesired oxide at the bottom of the contact hole, the contact hole is cleaned with hydrogen fluoride, or some other wet etch compound, to remove this small amount of oxide. The oxide at the bottom is undesired since it would be a barrier between the subsequently deposited contact plug 116 and the cell 100. Once cleaned, a thin layer of titanium 120 is deposited inside the contact hole, typically approximately 250 Å. Next, a thin layer of titanium nitride 122 is deposited into the contact hole. Then, the contact material 124, typically tungsten, is deposited into the contact hole. The titanium 120 serves as a glue layer between the substrate 102 and the contact plug 116, while the titanium nitride 122 serves as a barrier layer to prevent chemical reactions between the substrate 102 and the tungsten 122. The titanium 120, titanium nitride 122, and the tungsten 124 function together as the contact plug 116. The top of the plug 116 is then polished to prepare it for bonding with the metal line 114.

However, the cleaning of the contact hole with hydrogen fluoride not only removes the undesired oxide at the bottom of the contact hole, it also removes some desired oxide from the sides of the contact hole, causing the contact hole to enlarge in size. An enlarged contact hole leads to a larger than intended contact plug 116, which may prevent the metal line 118 from adequately covering the top of the plug 116. This causes circuit low conductivity, which may lead to device failure. This enlargement also becomes problematic as devices become smaller since it lowers the density of devices on the wafer. An additional problem occurs when there is a misalignment of the mask in the etching of the contact hole. Some amount of the field oxide 104 adjacent to the contact hole may be inadvertently etched during the hydrogen fluoride clean due to the contact hole enlargement, leading to a reduced contact with the drain region 110, which compromises the reliability of the device. The field oxide etch problem is also exacerbated as devices become smaller since the distance between the contact plug 116 and adjacent field oxide 104 also become smaller. This increases the chances of inadvertently etching the field oxide 104 in the event of a mask misalignment.

Accordingly, there exists a need for a method for better contact size control in flash memory devices. The method should remove undesired oxide at the bottom of the contact hole while also minimizing the enlargement of the contact hole. The method should reduce the chances of inadvertently etching field oxide adjacent to the contact hole. The present invention addresses such a need.

### SUMMARY OF THE INVENTION

The present invention provides a method for providing an interconnect in a flash memory device. A first embodiment includes forming at least one contact hole in a peripheral area of the device; bombarding a bottom of the at least one contact hole with ions, where the ions break down undesired oxide residing at the bottom of the at least one contact hole; depositing a barrier metal layer into the at least one contact hole, where the barrier metal layer breaks down remaining undesired oxide at the bottom of the at least one contact hole, and where bombarding with the ions and the depositing of the barrier metal layer minimize an undesired widening of the at least one contact hole; and depositing a contact material into the at least one contact hole. With the first embodiment, both the ions and the titanium break down the undesired oxide while neither breaks down the desired oxide at the sides of the contact hole to a significant degree. Thus, the undesired oxide at the bottom of the contact hole is removed while the enlargement of the contact hole is minimized. A second embodiment of the method, a contact hole having tapered sides with a top being wider than a bottom is used, where the tapered sides minimizes chances of inadvertently etching any field oxide adjacent to the contact hole. In a third embodiment of the method, the first and second embodiments are combined, minimizing the enlargement of the contact hole and the chances of inadvertently etching the field oxide simultaneously. The reliability of the device is thus increased.

### BRIEF DESCRIPTION OF THE FIGURES

FIG. 1 illustrates a cell 100 in the peripheral area in a conventional flash memory device.

FIG. 2 is a flow chart illustrating a first preferred embodiment of a method for providing contact size control in accordance with the present invention.

FIGS. 3A-3F illustrate cross-sections of a portion of a cell in the peripheral area in demonstration of the first preferred embodiment of the method for providing contact size control in accordance with the present invention.

FIG. 4 is a flow chart illustrating a second preferred embodiment of a method for providing contact size control in accordance with the present invention.

FIG. 5 illustrates a cross-section of a portion of a cell in the peripheral area in demonstration of the second preferred embodiment of the method for providing contact size control in accordance with the present invention.

FIG. 6 is a flow chart illustrating a third preferred embodiment of a method for providing contact size control in accordance with the present invention.

### DETAILED DESCRIPTION

The present invention provides a method for better contact size control in flash memory devices. The following description is presented to enable one of ordinary skill in the art to make and use the invention and is provided in the context of a patent application and its requirements. Various modifications to the preferred embodiment will be readily apparent to those skilled in the art and the generic principles herein may be applied to other embodiments. Thus, the present invention is not intended to be limited to the embodiment shown but is to be accorded the widest scope consistent with the principles and features described herein.

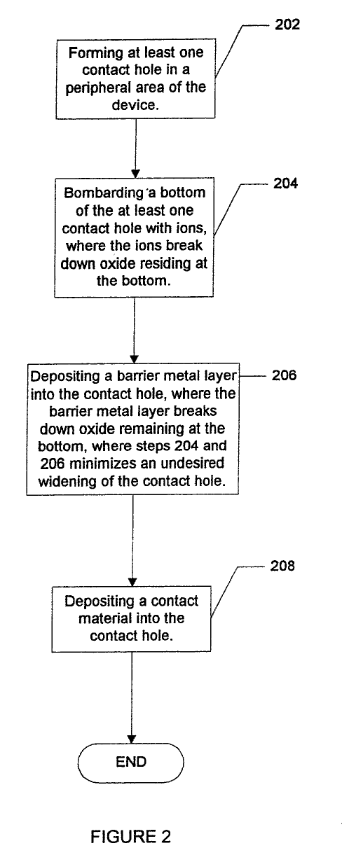

The method in accordance with the present invention provides better contact size control by eliminating the step of cleaning the contact hole prior to deposition of the contact plug and/or by using a tapered contact hole profile. By eliminating the cleaning step, the enlargement of the contact hole is minimized. By using a tapered contact hole profile, the chances of inadvertently etching field oxide adjacent to the contact hole is minimized. To more particularly describe the features of the present invention, please refer to FIGS. 2 through 5 in conjunction with the discussion below.

FIG. 2 is a flow chart illustrating a first preferred embodiment of a method for providing contact size control in accordance with the present invention. First, at least one contact hole is formed in a peripheral area of the device, via step 202. Next, a bottom of the at least one contact hole is bombarded with ions, where the ions break down oxide residing at the bottom, via step 204. In the first preferred embodiment, the bottom is bombarded with argon ions. Next, a barrier metal layer is deposited into the contact hole, via step 206, where the barrier metal layer breaks down oxide remaining at the bottom of the contact hole, where steps 204 and 206 minimize an undesired widening of the contact hole. In the first preferred embodiment, the barrier metal layer comprises a layer of titanium and a layer of titanium nitride. Then, a contact material is deposited into the contact hole, via step 208. In the first preferred embodiment, the contact material is tungsten.

With the first preferred embodiment of the method in accordance with the present invention, the problem of undesired oxide residing at the bottom of the contact hole after the contact hole formation is solved by eliminating the wet etch cleaning step. Instead, some of the undesired oxide at the bottom is broken down by the ions. Then, the layer of titanium breaks down the remaining oxide at the bottom. Since only the bottom of the contact hole is bombarded with the ions, the ions do not break down the desired oxide at the sides of the contact hole. The titanium does not breaks down the desired oxide at the sides of the contact hole to a significant degree. Thus, by using the ion bombardment and the titanium, the undesired oxide left at the bottom of the contact hole is removed while enlargement of the contact hole is minimized.

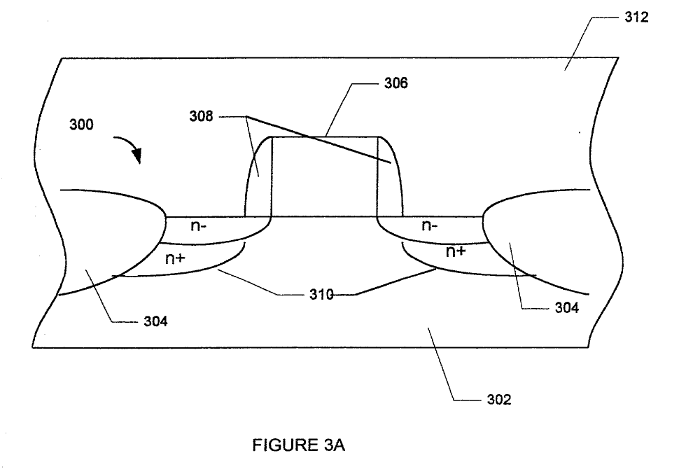

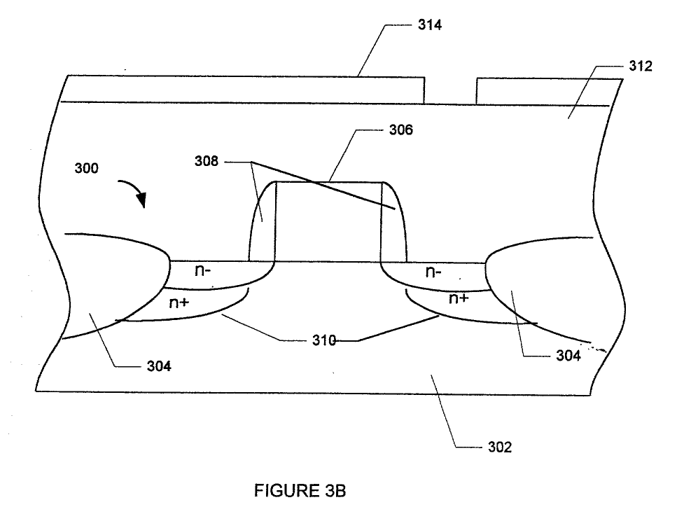

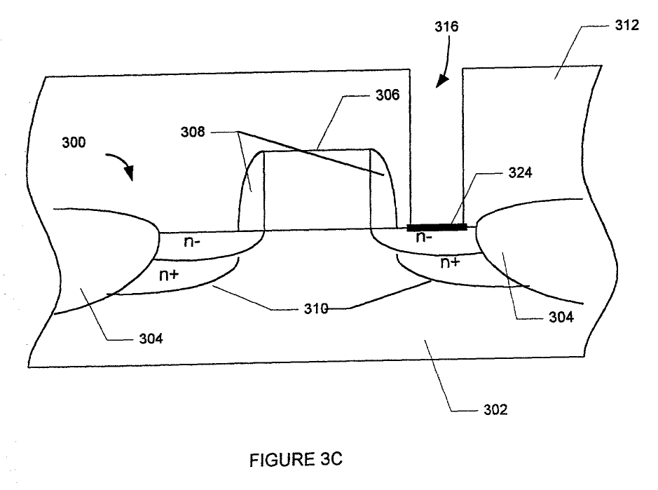

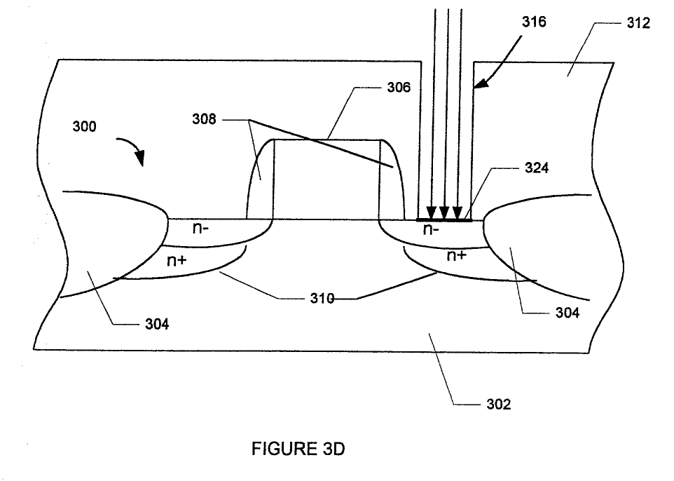

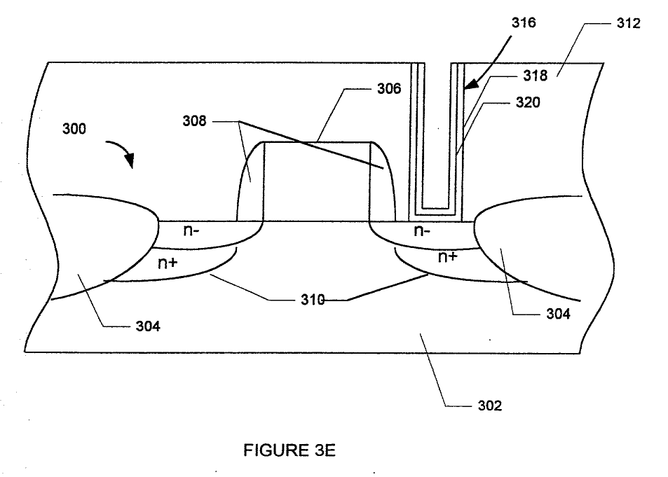

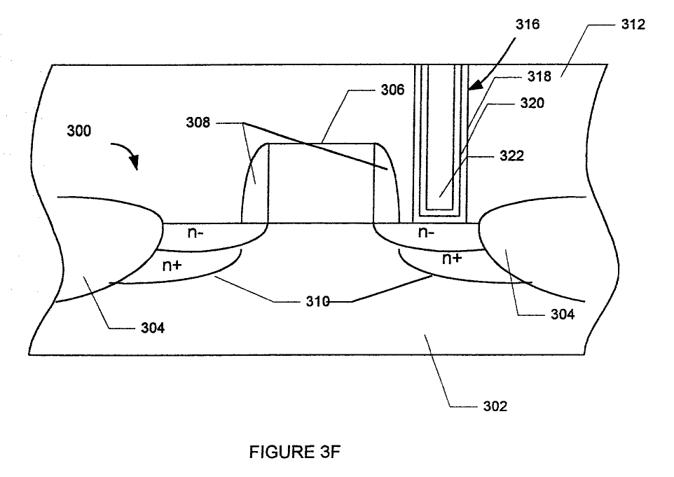

FIGS. 3A-3F illustrate cross-sections of a portion of a cell in the peripheral area in demonstration of the first preferred embodiment of the method for providing contact size control in accordance with the present invention. FIG. 3A illustrates a cell 300 in the peripheral area before the formation of an interconnect. The cell comprises a substrate 302, field oxide 304, a stack structure 306, spacers 308, and source/drain regions 310. Although a cell with n−/+ source/drain regions 310 is shown, they may also be p−/p+ source/drain regions. The cell 300 is covered by a layer of oxide 312 to insulate this layer of cells from subsequent layers of cells on the wafer (not shown). In the first preferred embodiment, the oxide 312 comprises about 14,800 Å of boron and phosphorus doped silicon glass.

FIGS. 3B and 3C illustrate the formation of the at least one contact hole, via step 202. As illustrated in FIG. 3B, a mask 314 is first placed on the oxide 312. As illustrated in FIG. 3C, the oxide 312 is then etched using photolithography techniques to form the contact hole 316. The mask 314 is then removed. The etch leaves a small amount of undesired oxide 324 at the bottom of the contact hole 316. This oxide 324 at the bottom needs to be removed in order to ensure a clean contact between the drain region 310 of the cell 300 and the interconnect.

To remove this undesired oxide 324 at the bottom of the contact hole 316, steps 204 and 206 (FIG. 2) are performed, as illustrated in FIGS. 3D and 3E. As shown in FIG. 3D, the bottom of the contact hole 316 is bombarded with ions, via step 204. In the preferred embodiment, the bottom only is bombarded with about 15 sccm of argon ions for approximately 8 seconds at about 5000 mT and 1000 W. The argon ions break down some of the undesired oxide 324 left at the bottom of the contact hole 316. Next, as shown in FIG. 3E, a layer of titanium 318 is deposited into the contact hole 316. In the first preferred embodiment, approximately 600 Å of collimated titanium is deposited at about 250°C. and 5000 mT. The titanium 318 breaks down the remaining undesired oxide 324 at the bottom of the contact hole 316. The undesired oxide 324 at the bottom is thus removed. Then, a layer of titanium nitride 320 is deposited into the contact hole 316. In the first preferred embodiment, approximately 150 Å of titanium nitride is deposited using chemical vapor deposition techniques at about 450°C. The titanium 318 and the titanium nitride 320 form the barrier metal layer. In addition to breaking down the remaining undesired oxide, the titanium 318 also serves as a glue layer between the resulting contact plug and the substrate 302. The titanium nitride 320 serves to prevent chemical reactions between the subsequently deposited contact material and the substrate 302.

Then, as illustrated in FIG. 3F, the contact material 322 is deposited into the contact hole, via step 208. In the first preferred embodiment, approximately 4000 Å of tungsten is deposited at about 440°C. A contact plug comprising the titanium 318, the titanium nitride 320, and the tungsten 322, is thus formed. The top of the contact hole 316 may then be polished to prepare the contact plug for bonding with a metal line (not shown).

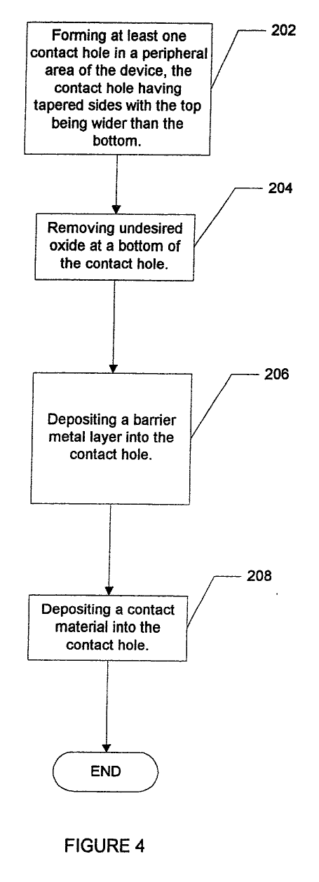

FIG. 4 is a flow chart illustrating a second preferred embodiment of a method for providing contact size control in accordance with the present invention. First, at least one contact hole is formed in a peripheral area of the device, via step 402, where the contact hole has tapered sides with the top being wider than the bottom. Next, the undesired oxide at the bottom of the contact hole is removed, via step 404. Next, a barrier metal layer is depositing into the contact hole, via step 406. In the second preferred embodiment, the barrier metal layer comprises a layer of titanium and a layer of titanium nitride. Then, a contact material is deposited into the contact hole, via step 408. In the second preferred embodiment, the contact material is tungsten.

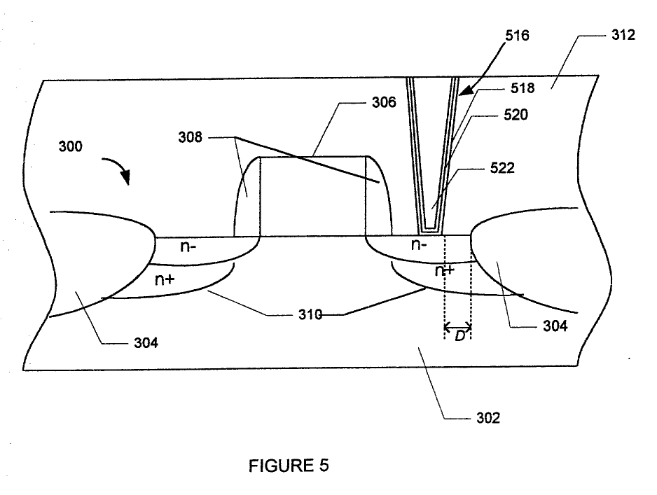

FIG. 5 illustrates a cross-section of a portion of a cell 300 in the peripheral area in demonstration of the second preferred embodiment. To form the contact hole 516, a mask is placed on the oxide 312, as with the first preferred embodiment (FIG. 3B). Then, the oxide 312 is etched to form the contact hole 516 with tapered sides. This may be accomplished in several ways. For example, the contact hole etch involves N₂ and CHF₃ gas. A polymer coating on the sides of the contact hole created by CHF₃ gas may be increased as the contact hole is etched. This polymer coating reduces the amount of oxide etched on the sides of the contact hole. The coating thickens as the contact hole etch progresses, causing less oxide to be etched near the bottom of the contact hole than at the top. This results in a contact hole with tapered sides. The thickening polymer coating may be accomplished by either reducing the amount N₂ gas used during the contact hole etch or increasing the amount of CHF₃ gas. In the second preferred embodiment, about 70 sccm of CHF₃ and about 65 sccm of N₂ is used.

For another example, the pressure of the contact hole etch may be varied to create the tapered profile. In the second preferred embodiment, a 3500 mT pressure is varied about +/− 10% to obtain the tapered sides. For still another example, the radio frequency power may be varied instead. In the second preferred embodiment, a 1600 W power is varied about +/−10% to obtain the tapered sides. The three examples above may also be combined, and other ways may be used.

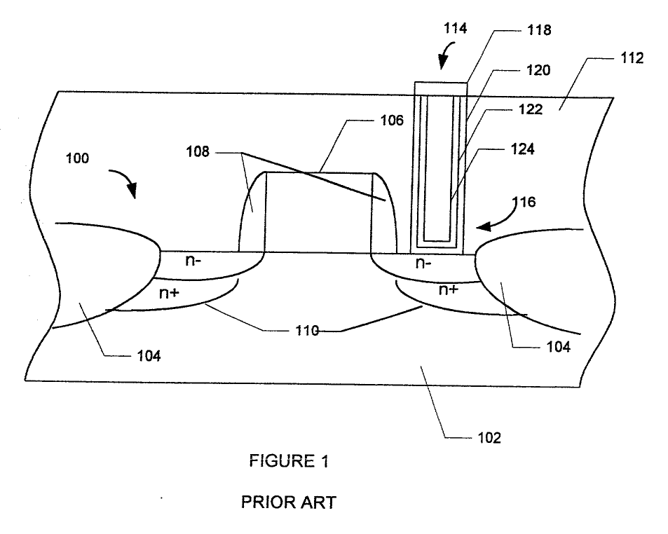

To remove the undesired oxide remaining at the bottom of the contact hole 516 from the contact hole etch, the conventional wet etch cleaning of the contact hole after the contact hole formation may be used. Even though the contact hole size is enlarged with this wet etch, the possibility of inadvertently etching the adjacent field oxide 304 due to mask misalignment during the contact hole etch is minimized since the distance D between the bottom of the contact hole 516 and the field oxide 304 has been increased. The barrier metal layer 518, 520 and the contact material 522 are then deposited into the contact hole 516 as is conventionally performed. The top of the contact hole 516 is the same approximate width as the contact hole 114 (FIG. 1), but the bottom of the contact hole 516 is of a smaller width. The well known limitations of photolithography continues to be addressed with the width of the top of the contact hole 516, while the distance D is increased. This advantage is maintained as devices become smaller. Thus, the reliability of the device is improved. Although the enlargement of the contact hole size may be minimized with the first preferred embodiment, the conventional wet etch cleaning is typically less expensive. Thus, the second preferred embodiment may be used to provide better contact size control without increasing the cost of fabricating the device.

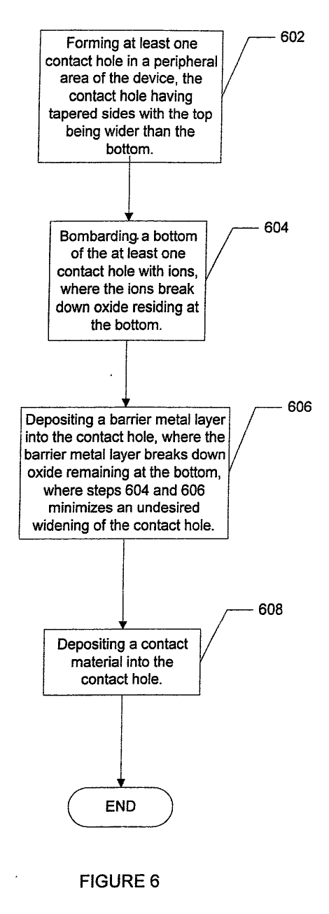

In a third preferred embodiment of the method for providing contact size control in accordance with the present invention, the first and second preferred embodiments are combined. FIG. 6 is a flow chart illustrating the third preferred embodiment. First, at least one contact hole is formed in a peripheral area of the device, via step 602, where the contact hole has tapered sides with the top being wider than the bottom. Next, a bottom of the at least one contact hole is bombarded with ions, where the ions break down oxide residing at the bottom, via step 604. In the third preferred embodiment, the bottom is bombarded with argon ions. Next, a barrier metal layer is deposited into the contact hole, via step 606, where the barrier metal layer breaks down oxide remaining at the bottom of the contact hole, where steps 604 and 606 minimize an undesired widening of the contact hole. Then, a contact material is deposited into the contact hole, via step 608. Step 602 is performed in the same manner as step 402 of the second preferred embodiment, while steps 604-608 are performed in the same manner as step 204-208, respectively, of the first preferred embodiment. With the third preferred embodiment, both the enlargement of the contact hole and the chances of inadvertent etching of field oxide adjacent to the contact hole are simultaneously minimized, further increasing the reliability of the device.

A method for better contact size control in flash memory devices has been disclosed. With a first preferred embodiment of the method in accordance with the present invention, undesired oxide residing at the bottom of a contact hole from the contact hole formation is removed utilizing a bombardment of the bottom with ions and a deposition of a layer of titanium into the contact hole. Both the ions and the titanium break down the undesired oxide while neither the ions nor the titanium breaks down the desired oxide at the sides of the contact hole to a significant degree. Thus, by using the first preferred embodiment of the method in accordance with the present invention, the undesired oxide at the bottom of the contact hole is removed while the enlargement of the contact hole is minimized. Because the contact hole is not enlarged, a metal line may adequately cover the top of the contact plug, preventing circuit low conductivity. The density of devices on the wafer is also not lowered. With a second preferred embodiment, the contact hole is formed with tapered sides, with the top of the contact hole being wider than the bottom The tapered contact hole profile increases the distance between the bottom of the contact hole and adjacent field oxide, minimizing the chances of inadvertently etching field oxide adjacent to the contact hole in the event of a mask misalignment in the contact hole etch. With a third preferred embodiment, the first and second preferred embodiments are combined. Thus, both the enlargement of the contact hole and the chances of inadvertently etching field oxide adjacent to the contact hole are simultaneously minimized. The reliability of the device is thus increased.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

What is claimed is:

1. A method for providing an interconnect in a flash memory device, comprising the sequential steps of:
(a) forming at least one contact hole in a peripheral area of the device;
(b) bombarding a bottom of the at least one contact hole with ions, wherein the ions break down undesired oxide residing at the bottom of the at least one contact hole;
(c) depositing a barrier metal layer into the at least one contact hole, wherein the barrier metal layer breaks down remaining undesired oxide at the bottom of the at least one contact hole, wherein steps (b) and (c) minimize an undesired widening of the at least one contact hole; and
(d) depositing a contact material into the at least one contact hole.

2. The method of claim 1, wherein the forming step (a) comprises the steps of:
(a1) positioning a mask on the peripheral area;
(a2) etching the peripheral area, wherein the at least one contact hole is formed; and
(a3) removing the mask.

3. The method of claim 1, wherein the bombarding step (b) comprises:
(b1) bombarding the bottom of the at least one contact hole with argon ions, wherein the argon ions break down the undesired oxide residing at the bottom of the contact hole.

4. The method of claim 3, wherein the bombarding step (b1) comprises:
(b1i) bombarding the bottom of the at least one contact hole with about 15 sccm of argon ions for approximately 8 seconds at about 5000 mT and 1000 W, wherein the argon ions break down the undesired oxide residing at the bottom of the contact hole.

5. The method of claim 1, wherein the depositing step (c) comprises sequentially the steps of:
(c1) depositing a layer of titanium into the at least one contact hole, wherein the titanium layer breaks down the remaining undesired oxide at the bottom of the at least one contact hole, wherein steps (b) and (c1) minimize the undesired widening of the at least one contact hole; and
(c2) depositing a layer of titanium nitride into the at least one contact hole.

6. The method of claim 5, wherein the depositing step (c1) comprises:
(c1i) depositing about 600 Å of collimated titanium into the at least one contact hole at about 250° C. and 5000 mT.

7. The method of claim 5, wherein the depositing step (c2) comprises:
(c2I) depositing about 150 Å of the titanium nitride using chemical vapor deposition techniques at about 450°C.

8. The method of claim 1, wherein the depositing step (d) comprises:
(d1) depositing a layer of tungsten into the at least one contact hole.

9. The method of claim 8, wherein the depositing step (d1) comprises:
(d1i) depositing about 4000 Å of the tungsten layer at about 440°C.

10. A method for providing an interconnect in a flash memory device, comprising the sequential steps of:
(a) forming at least one contact hole in a peripheral area of the device;
(b) bombarding a bottom of the at least one contact hole with argon ions, wherein the argon ions break down undesired oxide residing at the bottom of the at least one contact hole;
(c) depositing a layer of titanium into the at least one contact hole, wherein the titanium layer breaks down remaining undesired oxide at the bottom of the at least one contact hole, wherein steps (b) and (c) minimize an undesired widening of the at least one contact hole; and
(d) depositing a layer of titanium nitride into the at least one contact hole; and
(e) depositing a contact material into the at least one contact hole.

11. The method of claim 10, wherein the forming step (a) comprises the steps of:
(a1) positioning a mask on the peripheral area;
(a2) etching the peripheral area, wherein the at least one contact hole is formed; and
(a3) removing the mask.

12. The method of claim 10, wherein the bombarding step (b) comprises:
(b1) bombarding the bottom of the at least one contact hole with about 15 sccm of argon ions for approximately 8 seconds at about 5000 mT and 1000 W, wherein the argon ions break down the undesired oxide residing at the bottom of the contact hole.

13. The method of claim 10, wherein the depositing step (c) comprises:
(c1) depositing about 600 Å of collimated titanium into the at least one contact hole at about 250°C. and 5000 mT.

14. The method of claim 10, wherein the depositing step (d) comprises:
(d1) depositing about 150 Å of the titanium nitride using chemical vapor deposition techniques at about 450°C.

15. The method of claim 10, wherein the depositing step (e) comprises:
(e1) depositing a layer of tungsten into the at least one contact hole.

16. The method of claim 15, wherein the depositing step (e1) comprises:
(e1i) depositing about 4000 Å of the tungsten layer at about 440°C.

17. A method for providing an interconnect in a flash memory device, comprising the sequential steps of:
(a) positioning a mask on a peripheral area of the device;
(b) etching the peripheral area, wherein the at least one contact hole is formed;
(c) removing the mask;
(d) bombarding a bottom of the at least one contact hole with argon ions, wherein the argon ions break down undesired oxide residing at the bottom of the at least one contact hole;
(e) depositing a layer of titanium into the at least one contact hole, wherein the titanium layer breaks down remaining undesired oxide at the bottom of the at least one contact hole, wherein steps (d) and (e) minimize an undesired widening of the at least one contact hole; and
(f) depositing a layer of titanium nitride into the at least one contact hole;
(g) depositing a layer of tungsten into the at least one contact hole.

18. The method of claim 17, wherein the bombarding step (d) comprises:
(d1) bombarding the bottom of the at least one contact hole with about 15 sccm of argon ions for approximately 8 seconds at about 5000 mT and 1000 W, wherein the argon ions break down the undesired oxide residing at the bottom of the contact hole.

19. The method of claim 17, wherein the depositing step (e) comprises:
(e1) depositing about 600 Å of collimated titanium into the at least one contact hole at about 250°C. and 5000 mT.

20. The method of claim 17, wherein the depositing step (f) comprises:
(f1) depositing about 150 Å of the titanium nitride using chemical vapor deposition techniques at about 450°C.

21. The method of claim 17, wherein the depositing step (g) comprises:
(g1) depositing about 4000 Å of the tungsten layer at about 440°C.

22. A method for providing an interconnect in a flash memory device, comprising the sequential steps of:
(a) forming at least one contact hole in a peripheral area of the device, wherein the contact hole has tapered sides with a top being wider than a bottom of the at least one contact hole, wherein the tapered sides minimize chances of inadvertently etching any field oxide adjacent to the at least one contact hole;
(b) removing undesired oxide residing at the bottom of the at least one contact hole;
(c) depositing a barrier metal layer into the at least one contact hole; and
(d) depositing a contact material into the at least one contact hole.

23. The method of claim 22, wherein the forming step (a) comprises the steps of:
(a1) positioning a mask on the peripheral area;
(a2) etching the peripheral area, wherein the at least one contact hole with tapered sides is formed; and
(a3) removing the mask.

24. The method of claim 23, wherein the etching step (a2) is performed by increasing a polymer coating on the sides of the contact hole.

25. The method of claim 23, wherein the etching step (a2) is performed by varying a pressure level of the etch.

26. The method of claim 23, wherein the etching step (a2) is performed by varying a power level of the etch.

27. The method of claim 22, wherein the removing step (b) comprises:
(b1) removing the undesired oxide at the bottom of the contact hole using a wet etch.

28. The method of claim 22, wherein the removing step (b) comprises:
(b1) bombarding the bottom of the at least one contact hole with ions, wherein the ions break down the undesired oxide residing at the bottom of the at least one contact hole.

29. The method of claim 28, wherein the barrier metal layer breaks down remaining undesired oxide at the bottom of the at least one contact hole, wherein steps (b1) and (c) minimize an undesired widening of the at least one contact hole.

30. The method of claim 22, wherein the depositing step (c) comprises sequentially the steps of:
(c1) depositing a layer of titanium into the at least one contact hole; and
(c2) depositing a layer of titanium nitride into the at least one contact hole.

31. The method of claim 22, wherein the depositing step (d) comprises:
(d1) depositing a layer of tungsten into the at least one contact hole.

32. A method for providing an interconnect in a flash memory device, comprising the sequential steps of:
(a) forming at least one contact hole in a peripheral area of the device, wherein the contact hole has tapered sides with a top being wider than a bottom of the at least one contact hole, wherein the tapered sides minimize chances of inadvertently etching any field oxide adjacent to the at least one contact hole;
(b) bombarding the bottom of the at least one contact hole with ions, wherein the ions break down undesired oxide residing at the bottom of the at least one contact hole;
(c) depositing a barrier metal layer into the at least one contact hole, wherein the barrier metal layer breaks down remaining undesired oxide at the bottom of the at least one contact hole, wherein steps (b) and (c) minimize an undesired widening of the at least one contact hole; and
(d) depositing a contact material into the at least one contact hole.

33. The method of claim 32, wherein the forming step (a) comprises the steps of:
(a1) positioning a mask on the peripheral area;
(a2) etching the peripheral area, wherein the at least one contact hole with tapered sides is formed; and
(a3) removing the mask.

34. The method of claim 33, wherein the etching step (a2) is performed by increasing a polymer coating on the sides of the contact hole.

35. The method of claim 33, wherein the etching step (a2) is performed by varying a pressure level of the etch.

36. The method of claim 33, wherein the etching step (a2) is performed by varying a power level of the etch.

37. The method of claim 32, wherein the bombarding step (b) comprises:
(b1) bombarding the bottom of the at least one contact hole with argon ions, wherein the argon ions break down the undesired oxide residing at the bottom of the contact hole.

38. The method of claim 37, wherein the bombarding step (b1) comprises:
(b1i) bombarding the bottom of the at least one contact hole with about 15 sccm of argon ions for approximately 8 seconds at about 5000 mT and 1000 W, wherein the argon ions break down the undesired oxide residing at the bottom of the contact hole.

39. The method of claim 32, wherein the depositing step (c) comprises sequentially the steps of:
(c1) depositing a layer of titanium into the at least one contact hole, wherein the titanium layer breaks down the remaining undesired oxide at the bottom of the at least one contact hole, wherein steps (b) and (c1) minimize the undesired widening of the at least one contact hole; and
(c2) depositing a layer of titanium nitride into the at least one contact hole.

40. The method of claim 39, wherein the depositing step (c1) comprises:
(c1i) depositing about 600 Å of collimated titanium into the at least one contact hole at about 250°C. and 5000 mT.

41. The method of claim 39, wherein the depositing step (c2) comprises:
(c2I) depositing about 150 Å of the titanium nitride using chemical vapor deposition techniques at about 450°C.

42. The method of claim 32, wherein the depositing step (d) comprises:
(d1) depositing a layer of tungsten into the at least one contact hole.

43. The method of claim 42, wherein the depositing step (d1) comprises:
(d1i) depositing about 4000 Å of the tungsten layer at about 440°C.

45. A flash memory device, comprising:
a cell in a peripheral area of the device;
a field oxide proximate to the cell; and
an interconnect between the cell and the field oxide, wherein the contact hole has tapered sides with a top being wider than a bottom of the contact hole, wherein the tapered sides minimizes chances of inadvertently etching the field oxide.

46. The device of claim 45, wherein the interconnect further comprises:
a barrier metal layer in the contact hole, wherein the barrier metal layer breaks down undesired oxide at a bottom of the contact hole; and
a contact material in the contact hole.

47. The device of claim 46, wherein the barrier metal layer comprises:
a layer of titanium; and
a layer of titanium nitride.

48. The device of claim 46, wherein the contact material is tungsten.

49. A flash memory device, comprising:
a cell in a peripheral area of the device;
a field oxide proximate to the cell; and
an interconnect between the cell and the field oxide, wherein the contact hole has tapered sides with a top being wider than a bottom of the contact hole, wherein the tapered sides minimizes chances of inadvertently etching the field oxide, the interconnect comprising:
a layer of titanium, wherein the titanium layer breaks down undesired oxide at a bottom of the contact hole;
a layer of titanium nitride; and
a contact material comprising tungsten.
